(19) United States
(12) Patent Application Publication
(10) Pub. No.: US 2002/0140455 A1
(43) Pub. Date: Oct. 3, 2002

(54) Level shift circuit for stepping up logic signal amplitude with improved operating speed

(75) Inventor: Seiichiro Yamaguchi, Kawasaki (JP)

Correspondence Address: ARENT FOX KINTNER PLOTKIN & KAHN, PLLC, Suite 600, 1050 Connecticut Avenue, N.W., Washington, DC, 20036-5339, US

(73) Assignee: FUJITSU LIMITED

(21) Appl. No.: 09/988,616

(22) Filed: Nov. 20, 2001

(30) Foreign Application Priority Data
Mar. 30, 2001 (JP) 2001-098051

(51) Int. Cl. H03K 19/0175

(52) U.S. Cl. 326/81

(57) ABSTRACT

NMOS transistors N3 and N3S are connected in series between a PMOS transistor P1 and an NMOS transistor N1S constituting a first inverter connected between a power supply potential VDD2, which satisfies VDD1<VDD2, and a ground potential VSS, and likewise, NMOS transistors N4 and N4S are connected in series between a PMOS transistor P2 and an NMOS transistor N2S constituting a second inverter. The gate insulating films of the MOS transistors P1, P2, N3 and N4 are thicker than those of the transistors N1S and N4S. The gates of the NMOS transistors N3 and N4 are connected to VDD2, the gates of NMOS transistors N3S and N4S are connected to VDD1 and these transistors are constantly on.

### BACKGROUND OF THE INVENTION

1. Field of the Invention

The present invention relates generally to a level shift circuit, more particularly, to a level shift circuit having cross-coupled MOS transistors and disposed at a signal output stage in a CMOS integrated circuit device in order to step up a logic signal amplitude with an improved operating speed.

2. Description of the Related Art

In a CMOS integrated circuit, an operating voltage is scaled in almost proportion to the minimum size of MOS transistors, while a power supply voltage of a device such as a memory or hard disk device connected to the integrated circuit is maintained high with no relation to the scaling of the MOS transistors. Therefore, there have been many cases in which a power supply voltage provided externally is different from a power supply voltage used internally. In such cases, since input and output sections of the integrated circuit has an amplitude of a data signal different from that of an internal circuit, it is necessary to provide level shift circuits in the integrated circuit.

FIG. 5 shows a schematic configuration of a prior art CMOS integrated circuit 10 including a level shift circuit.

In the CMOS integrated circuit 10, a power supply voltage VDD2 is externally provided and stepped down to a power supply voltage VDD1 by a step-down circuit 20 to provide the stepped-down voltage VDD1 to a circuit 30 operating with a low voltage. For example, VDD2 and VDD1 are 3.3 V and 1.2 V, respectively. A level shift circuit 40 is provided in order to convert a data signal S1 with an amplitude VDD1 outputted from the circuit 30 to a data signal S0 with the amplitude VDD2 and to output the data signal SO outside of the CMOS integrated circuit 10.

The lower voltage operation circuit 30 and the level shift circuit 40 are different from each other in transistor size and formed with different technologies. That is, in the lower voltage operation circuit 30 and the level shift circuit 40, there are used transistors having the thicknesses of gate insulating film and gate lengths optimized for operations under the respective power supply voltages VDD1 and VDD2. More specifically, the thickness of gate insulating film of transistors in the level shift circuit 40 is more than that in the lower voltage operation circuit 30, and the threshold voltage Vthn of NMOS transistors N1 and N2 in the level shift circuit 40 is higher than that in the lower voltage operation circuit 30.

For this reason, as the power supply voltage VDD1 lowers according to the miniaturization of transistors in the lower voltage operation circuit 30, VDD1 comes to be closer to the threshold voltage Vthn of the NMOS transistors N1 and N2, and when the NMOS transistors N1 and N2 are turned on by the lower voltage operation circuit 30, the on-resistance of the transistors becomes large with a small current value, so the operating speed of the level shift circuit 40 is lowered.

### SUMMARY OF THE INVENTION

Accordingly, it is an object of the present invention to provide a level shift circuit capable of operating at a higher speed.

In one aspect of the present invention, there is provided a level shift circuit comprising: first and second PMOS transistors cross-coupled to each other and each having a source electrode connected to the power supply potential VDD2; and first and second NMOS transistors each having a source electrode connected to the reference potential VSS, a drain electrode, and a gate electrode, the drain electrodes thereof being coupled to the drain electrodes of the first and second PMOS transistors to form first and second inverters, respectively, the gates thereof receiving respective complementary signals SI and *SI which are generated by a circuit operating under a voltage between a power supply potential VDD1 (VDD1<VDD2) and the reference potential VSS; wherein a thickness of gate insulating films of the first and second NMOS transistors is less than that of the first and second PMOS transistors.

With this configuration, since the current driving capability of NMOS transistors of the first and second inverters increases for the same input driving signal pair SI and *SI, these NMOS transistors are turned on/off at a higher speed, and thereby the operation of the level shift circuit becomes faster than that of the prior art.

In another aspect of the present invention, the level shift circuit further comprises: a third NMOS transistor coupled between the first PMOS transistor and the first NMOS transistor, having a gate electrode connected to a given potential VAA (VDD1≦VAA≦VDD2) ; and a fourth NMOS transistor coupled between the second PMOS transistor and the second NMOS transistor, having a gate electrode connected to the given potential VAA.

With this configuration, since the maximum value of the drain to gate voltage of the NMOS transistors of the first and second inverters lowers down to VAA−Vthni by the inserted NMOS transistors, where Vthni is the threshold voltage of the inserted NMOS transistors, a lower power supply potential VDD1 can be used.

In still another aspect of the present invention, the level shift circuit further comprises: a fifth NMOS transistor coupled between the third NMOS transistor and the first NMOS transistor, having a gate electrode and a gate insulating film; and a sixth NMOS transistor coupled between the fourth NMOS transistor and the second NMOS transistor, having a gate electrode and a gate insulating film; wherein each gate electrode of the fifth and sixth NMOS transistors is connected to the power supply potential VDD1, and a thickness of each gate insulating film of the fifth and sixth NMOS transistors is substantially equal to that of the first and second NMOS transistors.

With such a configuration, since the drain to gate voltage of the inserted fifth and sixth NMOS transistors with a smaller gate insulating film thickness is reduced by the inserted third and fourth NMOS transistors with a larger insulting film thickness, and the drain to gate voltages of the first and second NMOS transistors with the smaller gate insulating film thickness of first and second inverters are reduced by the inserted NMOS transistors with the smaller gate insulating film thickness, a margin for the withstand voltage of the transistors with the smaller gate insulating film thickness becomes larger, thereby enabling to use a lower power supply potential VDD1.

Other aspects, objects, and the advantages of the present invention will become apparent from the following detailed description taken in connection with the accompanying drawings.

### BRIEF DESCRIPTION OF THE DRAWINGS

FIG. 1 is a schematic diagram of a CMOS integrated circuit to which a level shift circuit of a first embodiment according to the present invention is applied;

FIG. 2 is a schematic diagram of a CMOS integrated circuit to which a level shift circuit of a second embodiment according to the present invention is applied;

FIG. 3 is a schematic diagram of a CMOS integrated circuit to which a level shift circuit of a third embodiment according to the present invention is applied;

FIG. 4 is a schematic diagram of a CMOS integrated circuit to which a level shift circuit of a fourth embodiment according to the present invention is applied; and

FIG. 5 is a schematic diagram of a prior art CMOS integrated circuit including a level shift circuit.

### DESCRIPTION OF THE PREFERRED EMBODIMENTS

Referring now to the drawings, wherein like reference characters designate like or corresponding parts throughout several views, preferred embodiments of the present invention are described below.

First Embodiment

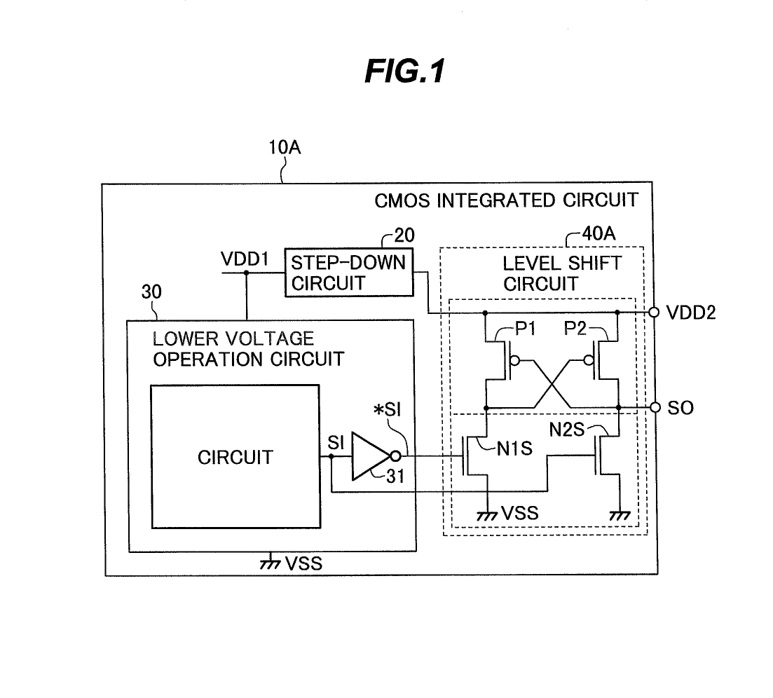

FIG. 1 shows a schematic configuration of a CMOS integrated circuit 10A to which a level shift circuit 40A of a first embodiment according to the present invention is applied.

In the level shift circuit 40A, a PMOS transistor P1 and an NMOS transistor N1S are connected in series between a power supply potential VDD2 and a reference potential VSS=0 V to constitute a first inverter, and likewise a PMOS transistor P2 and an NMOS transistor N2S are connected in series between the power supply potential VDD2 and the reference potential VSS=0 V to constitute a second inverter. Furthermore, the PMOS transistors P1 and P2 are cross-connected to each other to constitute a flip-flop. That is, the gates of the PMOS transistors P1 and P2 are connected to the drains of the NMOS transistors N2S and N1S, respectively. A data signal SI is provided to the gate of the NMOS transistor N2S from a circuit of a lower voltage operation circuit 30 and a data signal *SI obtained by inverting a logic value of the data signal SI at an inverter 31 is given to the gate of the NMOS transistor N1S.

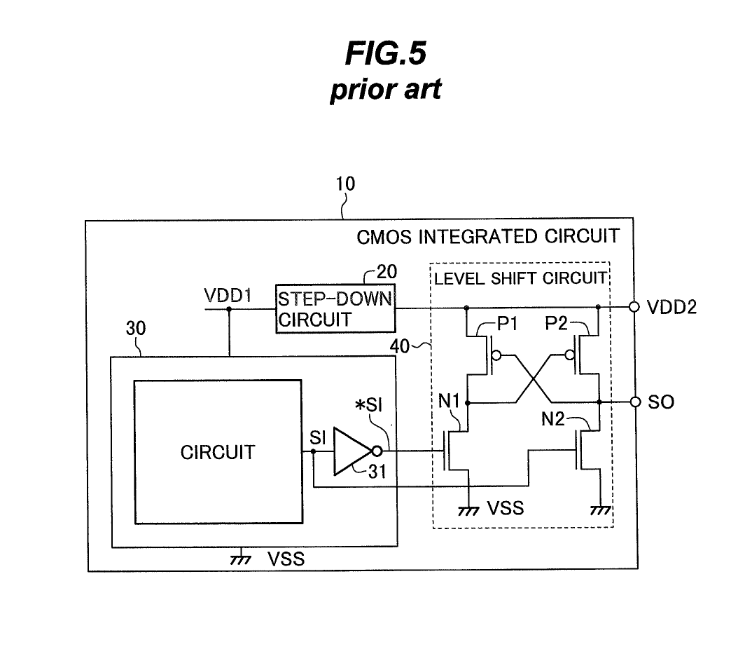

The NMOS transistors N1S and N2S are formed in the same CMOS fabrication process as that of the lower voltage operation circuit 30, and therefore the thickness of gate insulating films of the NMOS transistors N1S and N2S are equal to that of the lower voltage operation circuit 30 if a variation in thickness in the fabrication is neglected. On the other hand, the thickness of the PMOS transistors P1 and P2 are larger than that of the NMOS transistors N1S and N2S. Therefore, the threshold voltage Vthns of the NMOS transistors N1S and N2S is lower than corresponding Vthn of FIG. 5, and the driving capability of the input signals SI and *SI for the transistors becomes relatively large.

In the above configuration, since a difference between a gate potential VDD1 when a NMOS transistor N1S or N2S is on and the threshold voltage Vthns thereof is larger than corresponding difference VDD1−Vthn in the case of FIG. 5, when the signal SI transits from low to high, that is, when the gate potentials of the NMOS transistors N2S and N1S alters to VDD1 and 0 V, respectively, the NMOS transistors N2S and N1S transit to on and off states, respectively, at a high speed. Accordingly, a current flows from a signal output SO through the NMOS transistor N2S to ground at a high speed to achieve a high speed operation.

Since the signal SO becomes low by turning-on of the NMOS transistor N2S, the PMOS transistor P1 is turned on, and thereby the gate potential of the PMOS transistor P2 becomes VDD2 to turn off the PMOS transistor P2.

Then, when the signal SI transits to low, that is, when the gate potentials of the NMOS transistors N2S and N1S alter to 0 V and VDD1, respectively, the NMOS transistors N1S and N2S transit to on and off states, respectively, at a high speed. With such transitions, the gate of the PMOS transistor P2 becomes low, the PMOS transistor P2 is turned on at a high speed, and a current flows from VDD2 through the PMOS transistor P2 to the signal output SO, thereby enabling high speed operation.

The gate potential of the PMOS transistor P1 becomes VDD2 by turning-on of the PMOS transistor P2, thereby turning off the PMOS transistor P1.

Second Embodiment

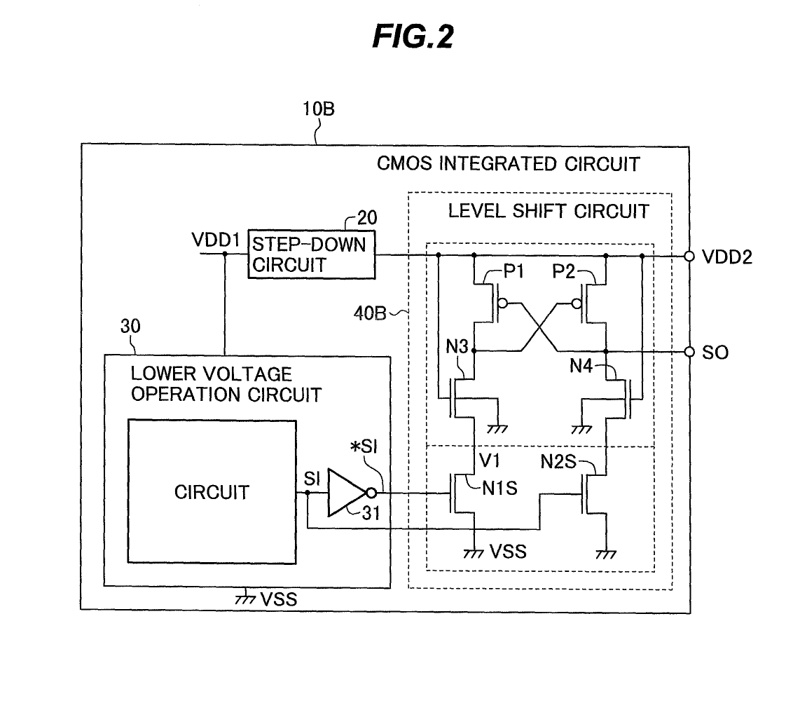

FIG. 2 shows a schematic configuration of a CMOS integrated circuit 10B to which a level shift circuit 40B of a second embodiment according to the present invention is applied.

In FIG. 1, when *SI=VSS, the PMOS transistor P1 and the NMOS transistor N1S are on and off, respectively, and the drain to gate voltage of the NMOS transistor N1S becomes the maximum value VDD2. For this reason, there arise a restriction that the level shift circuit 40A cannot be used in a case where the power supply voltage VDD2 is so high that gate insulating films of the NMOS transistors N1S and N2S are broken down.

Therefore, in order to alleviate this restriction, in the level shift circuit 40B of FIG. 2, an NMOS transistor N3 is connected between the drain of the PMOS transistor P1 and the drain of the NMOS transistor N1S, an NMOS transistor N4 is connected between the drain of the PMOS transistor P2 and the drain of the NMOS transistor N2S, and the gates of the NMOS transistors N3 and N4 are connected to VDD2. With such a configuration, the NMOS transistors N3 and N4 are constantly in an on state. The NMOS transistors N3 and N4 are fabricated in the same fabrication process as that of the PMOS transistors P1 and P2, and thereby the thicknesses of gate insulating films of these transistors are equal to each other if a variation in thickness in the fabrication is neglected. The back gates of the NMOS transistors N3 and N4 are connected to VSS.

Since the NMOS transistors N3 and N4 are constantly in an on state, the logic operation of the level shift circuit 40B for the signal SI is the same as that of FIG. 1.

The drain potential V1 of the NMOS transistor N1S is 0 V when the NMOS transistor N1S and the PMOS transistor P1 are on and off, respectively, while being VDD2−Vthn when the NMOS transistor N1S and the PMOS transistor P1 are off and on, respectively, wherein Vthn is the threshold voltage of the NMOS transistor N3. Therefore, a range in which V1 varies is given by the following expression:

0≦V1≦VDD2−Vthn.

Since a reverse voltage−Vis applied between the back gate and source of the NMOS transistor N3, the threshold voltage Vthn becomes higher than the threshold voltage Vthn₀ in a case where the back gate to source voltage is 0 V, and as a result, V1 further lowers to reduce the drain to gate voltage Vdg of the NMOS transistor N1S. The voltage Vdg becomes the maximum value Vdgmax=VDD2−Vthn when the signal *SI is at VSS, and with the Vdgmax lower than that in the case of FIG. 1 by Vthn, the above restriction is alleviated. For example, when VDD2=3.3 V, VDD1=1.1 V and Vthn₀=1.5 V, Vthn=2.0 V and Vdgmax=1.3 V. This applies to the drain to gate voltage of the NMOS transistor N2S in a similar manner.

Although the on-resistance value of the NMOS transistors N3 and N4 increases because of Vthn₀<Vthn, it was confirmed by simulation that the operation of the level shit circuit 40B is much faster than that of the level shift circuit 40 of FIG. 5 (a high speed of about 10,000 times on the conditions of VDD1=1.2 V and VDD2=3.3 V).

Third Embodiment

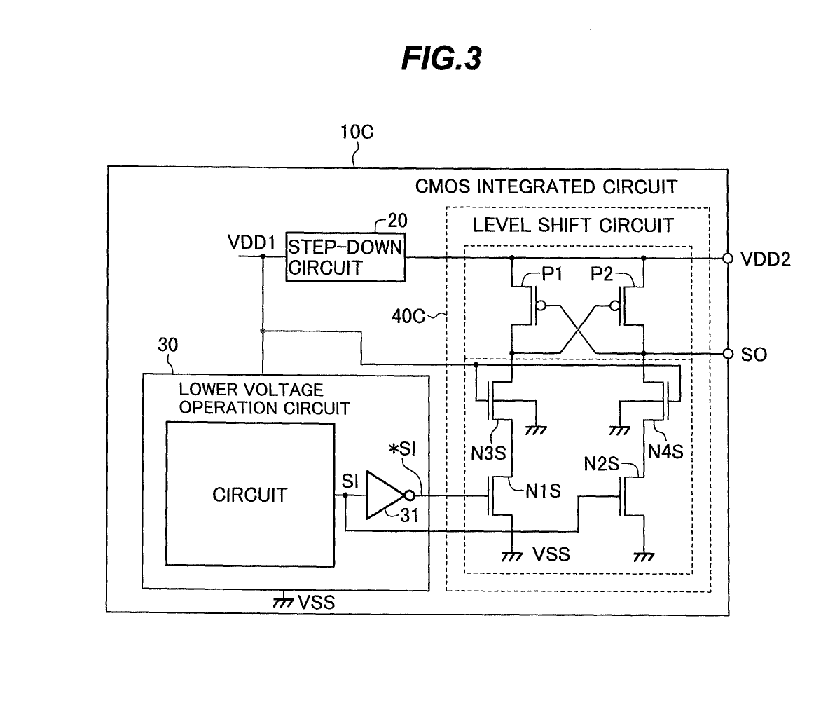

FIG. 3 shows a schematic configuration of a CMOS integrated circuit 10C to which a level shift circuit 40C of a third embodiment according to the present invention is applied.

In this circuit, instead of the NMOS transistors N3 and N4 of FIG. 2, used are NMOS transistors N3S and N4S formed in the same CMOS fabrication process as that of the lower voltage operation circuit 30. Therefore, the gate thickness of the NMOS transistors N3S and N4S is equal to that of the NMOS transistors N1S and N2S if a variation in thickness in the fabrication is neglected. The gates of NMOS transistors N1S and N2S are applied with VDD1 and these transistors are constantly on. The back gates of the NMOS transistors N3S and N4S are connected to VSS.

The drain to gate maximum voltage of the NMOS transistor N1S is equal to Vdgmax=VDD1−Vthns, where Vthns is the threshold voltage of the NMOS transistor N3S, and lower than that in the case of FIG. 3. For example, when VDD2=3.3 V, VDD1=1.7 V and Vthns=0.8 V, Vdgmax=0.9 V. This applies to the drain to gate voltage of the NMOS transistor N2S in a similar manner.

As a result of simulation, it was confirmed that the level shift circuit 40C is faster in operation speed than that of the level shift circuit 40B of FIG. 2.

Fourth Embodiment

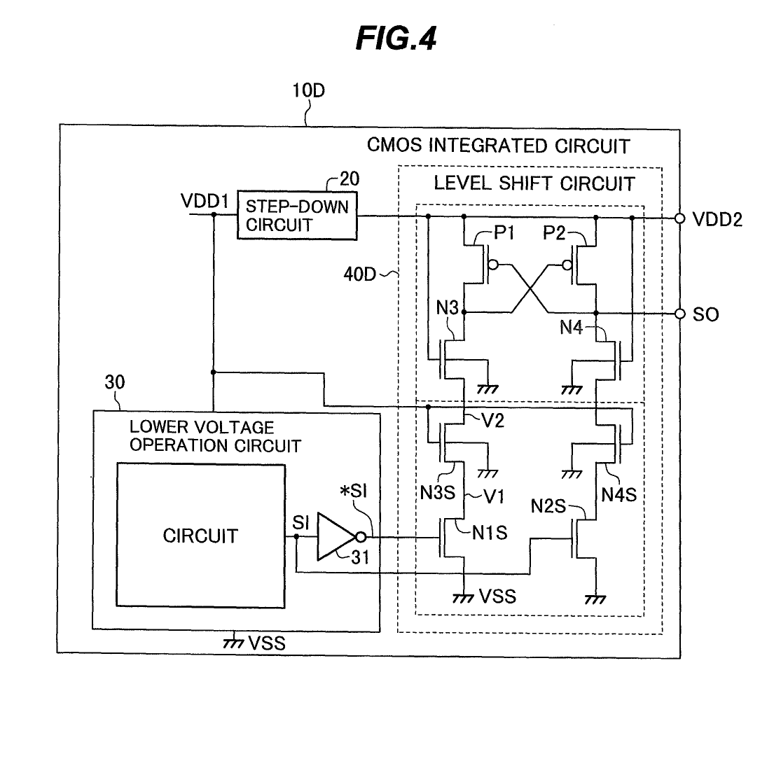

FIG. 4 shows a schematic configuration of a CMOS integrated circuit 10D to which a level shift circuit 40D of a fourth embodiment according to the present invention is applied.

In a case where the level shift circuit 40C of FIG. 3, since the drain to gate maximum voltage of the NMOS transistor N3S is equal to VDD2−VDD1, there is a restriction that as a withstand voltage condition for the NMOS transistors N3S and N4S, a relation VDD2−VDD1≦VDD1 must hold, that is, VDD2/2≦VDD1 must be satisfied.

Hence, in order to alleviate the restriction, in the level shift circuit 40D of FIG. 4, the NMOS transistor N3 of FIG. 2 and the NMOS transistor N3S of FIG. 3 are connected in series between the drain of the PMOS transistor P1 and the drain of the NMOS transistor N1S, and likewise the NMOS transistor N4 of FIG. 2 and the NMOS transistor N4S of FIG. 3 are connected in series between the drain of the PMOS transistor P2 and the drain of the NMOS transistor N2S. The gates of the NMOS transistors N3 and N4 are connected to VDD2, while the gates of the NMOS transistors N3S and N4S are connected to VDD1. The back gates of the NMOS transistors N3, N4, N3S and N4S are all connected to VSS.

The drain potential V2 of the NMOS transistor N3S is equal to VDD2−Vthn, and therefore the drain to gate voltage Vdg of the NMOS transistor N3S is VDD2−Vthn−VDD1. That is, the Vdg is lower than that in the case of FIG. 3 by the threshold voltage Vthn of the NMOS transistor N3. For example, when VDD2=3.3 V and VDD1=1.2 V, Vdg is equal to about 1.2 V if Vthn is adjusted to be about 0.8 V; therefore, the breakdown of the gate insulating film of the NMOS transistor N3S can be sufficiently prevented. Further, since the source potential V1 of the NMOS transistor N3S is equal to VDD1—Vthns, the drain to source voltage of the NMOS transistor N3S is equal to V2—V1=VDD2—Vthn—VDD1 +Vthns. In the above example, when Vthns=0.2 V, the drain to source voltage V2—V1 is equal to about 3.3−0.8−1.2+0.2=1.5 V, which is slightly higher. However, since a drain to source withstand voltage is usually much higher than the withstand voltage of a gate insulating film, this value is not problematical.

According to the level shift circuit 40D of the fourth embodiment, since a margin for a transistor withstand voltage is larger than that in the above second and third embodiments, VDD1 can be set to a much lower value in relation to VDD2. For example, when VDD2=3.3 V, VDD1 can be set at a value in the range of 0.6 to 0.8 V without producing a problem associated with withstand voltage.

Although the operating speed of the level shift circuit 40D is theoretically a little lower than that of the level shift circuit 40C of FIG. 3, almost the same speed was confirmed therebetween as a result of simulation.

Although preferred embodiments of the present invention has been described, it is to be understood that the invention is not limited thereto and that various changes and modifications may be made without departing from the spirit and scope of the invention.

For example, potentials applied onto the gates of the inserted NMOS transistors N3 and N4 or N3S and N4S are not limited to the above values, but any value may be applied as far as the value is not problematical in terms of withstand voltage and the drain to gate voltage of low voltage NMOS transistors can be reduced.

What is claimed is:

1. A level shift circuit for converting complementary signals SI and *SI out of a CMOS circuit operating under a power supply voltage between a first power supply potential and a reference potential to an output signal SO for a circuit operating under a power supply voltage between a second power supply potential, which is higher than said first power supply potential, and said reference potential, said level shift circuit comprising:
first and second PMOS transistors each having a source electrode connected to said second power supply potential, a drain electrode, and a gate electrode, said gate and drain electrodes of said first PMOS transistor being connected to said drain and gate electrodes of said second PMOS transistor, respectively, said drain electrode of said second PMOS transistor providing said output signal SO; and
first and second NMOS transistors each having a source electrode connected to said reference potential, a drain electrode, and a gate electrode, said drain electrodes thereof being coupled to said drain electrodes of said first and second PMOS transistors, respectively, said gates thereof receiving respective said complementary signals SI and *SI;
wherein a thickness of gate insulating films of said first and second NMOS transistors is less than that of said first and second PMOS transistors.

2. The level shift circuit of claim 1, further comprising:
a third NMOS transistor coupled between said first PMOS transistor and said first NMOS transistor, having a gate electrode connected to a given potential which is in a range from said first power supply potential to said second power supply potential; and
a fourth NMOS transistor coupled between said second PMOS transistor and said second NMOS transistor, having a gate electrode connected to said given potential.

3. The level shift circuit of claim 2, wherein said given potential is equal to said second power supply potential and a thickness of gate insulating films of said third and fourth NMOS transistors is substantially equal to that of said first and second PMOS transistors.

4. The level shift circuit of claim 2, wherein said given potential is equal to said first power supply potential and a thickness of gate insulating films of said third and fourth NMOS transistors is substantially equal to a thickness of said first and second NMOS transistors.

5. The level shift circuit of claim 2, wherein said reference potential is applied to back gates of said third and fourth NMOS transistors.

6. The level shift circuit of claim 3, wherein said reference potential is applied to back gates of said third and fourth NMOS transistors.

7. The level shift circuit of claim 4, wherein said reference potential is applied to back gates of said third and fourth NMOS transistors.

8. The level shift circuit of claim 3, further comprising:
a fifth NMOS transistor coupled between said third NMOS transistor and said first NMOS transistor, having a gate electrode and a gate insulating film; and
a sixth NMOS transistor coupled between said fourth NMOS transistor and said second NMOS transistor, having a gate electrode and a gate insulating film;
wherein each gate electrode of said fifth and sixth NMOS transistors is connected to said first power supply potential, and a thickness of each gate insulating film of said fifth and sixth NMOS transistors is substantially equal to that of said first and second NMOS transistors.

9. A CMOS integrated circuit device comprising: a level shift circuit for converting complementary signals SI and *SI out of a CMOS circuit operating under a power supply voltage between a first power supply potential and a reference potential to an output signal SO for a circuit operating under a power supply voltage between a second power supply potential, which is higher than said first power supply potential, and said reference potential, said level shift circuit comprising:
first and second PMOS transistors each having a source electrode connected to said second power supply potential, a drain electrode, and a gate electrode, said gate and drain electrodes of said first PMOS transistor being connected to said drain and gate electrodes of said second PMOS transistor, respectively, said drain electrode of said second PMOS transistor providing said output signal SO; and
first and second NMOS transistors each having a source electrode connected to said reference potential, a drain electrode, and a gate electrode, said drain electrodes thereof being coupled to said drain electrodes of said first and second PMOS transistors, respectively, said gates thereof receiving respective said complementary signals SI and *SI;
wherein a thickness of gate insulating films of said first and second NMOS transistors is less than that of said first and second PMOS transistors.

10. The CMOS integrated circuit device of claim 9, further comprising:
a third NMOS transistor coupled between said first PMOS transistor and said first NMOS transistor, having a gate electrode connected to a given potential which is in a range from said first power supply potential to said second power supply potential; and
a fourth NMOS transistor coupled between said second PMOS transistor and said second NMOS transistor, having a gate electrode connected to said given potential.

11. The CMOS integrated circuit device of claim 10, wherein said given potential is equal to said second power supply potential and a thickness of gate insulating films of said third and fourth NMOS transistors is substantially equal to that of said first and second PMOS transistors.

12. The CMOS integrated circuit device of claim 10, wherein said given potential is equal to said first power supply potential and a thickness of gate insulating films of said third and fourth NMOS transistors is substantially equal to a thickness of said first and second NMOS transistors.

13. The CMOS integrated circuit device of claim 10, wherein said reference potential is applied to back gates of said third and fourth NMOS transistors.

14. The CMOS integrated circuit device of claim 11, wherein said reference potential is applied to back gates of said third and fourth NMOS transistors.

15. The CMOS integrated circuit device of claim 12, wherein said reference potential is applied to back gates of said third and fourth NMOS transistors.

16. The CMOS integrated circuit device of claim 11, further comprising:
a fifth NMOS transistor coupled between said third NMOS transistor and said first NMOS transistor, having a gate electrode and a gate insulating film; and
a sixth NMOS transistor coupled between said fourth NMOS transistor and said second NMOS transistor, having a gate electrode and a gate insulating film;
wherein each gate electrode of said fifth and sixth NMOS transistors is connected to said first power supply potential, and a thickness of each gate insulating film of said fifth and sixth NMOS transistors is substantially equal to that of said first and second NMOS transistors.
